(19) United States
(12) Patent Application Publication
(10) Pub. No.: US 2022/0019259 A1
(43) Pub. Date: Jan. 20, 2022

(54) DEPLOYABLE PERSONAL COMPUTER CASE

(71) Applicants: Irakli PETRIASHVILI, Tbilisi (GE); Vasil PETRIASHVILI, Tbilisi (GE)

(72) Inventors: Irakli PETRIASHVILI, Tbilisi (GE); Vasil PETRIASHVILI, Tbilisi (GE)

(21) Appl. No.: 17/432,691

(22) PCT Filed: Feb. 21, 2020
(86) PCT No.: PCT/GE2020/050001

§ 371 Date: Aug. 20, 2021

(30) Foreign Application Priority Data
Feb. 22, 2019 (GE) AP 2019 15012

(51) Int. Cl. G06F 1/16; H05K 7/20; H05K 5/04

(52) U.S. Cl. CPC G06F 1/1615; H05K 5/04; H05K 7/20136; G06F 1/1628

(57) ABSTRACT

A computer case has a main section, a rear section capable of being pivoted relative to the main section and a display section capable of being pivoted relative to the main section, and a display section capable of being pivoted relative to the main section. The display section is pivotally connected to the main section with the capability of being pivoted with respect to the main section between a first stowed position, where the display section covers the main section and a portion of the rear section, and a second deployed position, where the display section is raised from the main section to be disposed substantially perpendicular to the main section and in in-line alignment with a frontal surface of the main section. The rear section is pivotally connected to the main section with the capability of being pivoted with respect to the main section substantially about a horizontal axis of rotation.

### TECHNICAL FIELD

The present invention pertains to the personal computer case, in particular to the case capable of being stowed and deployed in order to ease its carriage and conveniently place onto a working area.

### BACKGROUND ART

At present personal computers play important role in the modern office and household activities alike. The majority of the personal computers can be categorized as so called notebooks that are particularly convenient to carry, and desktop computers that are motionlessly placed in office and home working areas.

The modern notebooks are usually characterized by thin design and light weight, while the desktop computers consume relatively large working space due to their dimensions. Moreover, the desktop computers are in need of cables with the length sufficient for connecting to peripheral devices that makes them inconvenient in use and worsens their external appearance.

By way of an example, an earlier generation desktop computer is depicted in FIG. 1, which is equipped with a cathode ray tube display as a peripheral device, which, as can be seen from the figure, makes the desktop computer a consumer of a large working space.

Notwithstanding the fact that eventually relatively smaller, so called flat screen monitors, mainly with liquid crystal and light emitting diode screens, became widely used, the working space needed for the personal computer was not reduced significantly, as is clearly shown in FIG. 2.

On the other hand, despite the compact computers, so called notebooks, are characterized with small dimensions and it is rather convenient to carry them from one place to another, they are characterized with a number of drawbacks. In particular, such computers comprise a processor and keyboard structure fully integrated with their stowable case, wherein a liquid crystal display is accommodated with the capability of pivoting. Due to such a structure, distance between the keyboard and liquid crystal display is limited, thus making the user feel uncomfortable. Moreover, computational power of such type of devices are also limited due to the thin design of their case not allowing sufficiently large details, such as for example coolers, to be accommodated therein. Nowadays, the existing notebook monitor sizes are also limited (do not exceed 19 inches). Obviously the foregoing eventually has effect on the computer performance.

In addition, behind the development of computer systems, memory and data processing performances are significantly enhanced. In order for the user to be able to handle high quality multimedia data, as well as to operate modern graphical software and the like, he/she has to use a desktop personal computer having, as was stated above, separately arranged central processor unit, monitor, keyboard and etc. that are connected to one another by means of cables. Such a system interconnected units and devices and components is completely inconvenient to carry from one place to another, unlike a notebook that can be carried very easily. For example, a computer user has to detach all components when carrying and then to assemble them again when computer is put on a place. This, in addition to inconvenience, can cause an operation disturbance. A notebook, on the other hand, is not suitable for working with multimedia materials due to the limitations in terms of processing power. It should also be noted herein that high performance notebooks cost twice or even three times as much as desktop computers having the same performance.

Taking the modern demands into consideration, especially that the carriageability of a computer is a matter of great importance, it became necessary to develop a portable computer having the same performance as a desktop computer in terms of data processing ability.

One such a computer is disclosed for example in U.S. Pat. No. 4,832,419, namely a mechanism for adjusting the height and viewing angle of a flat panel display which is viewed in conjunction with a portable personal computer. The mechanism includes a pair of arms that swing the display panel between the lowered and raised position. In a lowered position the flat panel display may be securely latched to the portable personal computer to protect the display from damage. The upper housing is connected to the base housing in a manner permitting the upper housing to be tilted forwardly and rearwardly relative to the base housing to permit a user of the computer to adjust the viewing angle of a display screen structure fixedly secured to a front side of the upper housing.

The portable computers disclosed in the aforementioned patents still require relatively large space when placed on a working area despite the suitability for being carried with their components placed in a single case. This is because the computer case structure itself does not change when being carried and when it is placed on a working area.

Therefore the present invention has for its objective to create a computer case capable of improving the use of a working area and the operation of a desktop computer.

### SUMMARY OF THE INVENTION

In accordance with the present invention, a computer case consists of three sections:
a main section;
a rear section that is designed to be pivotable relative to the main section; and
a display section that is designed to be pivotable relative to the main section.

The display section is made to be pivotable with respect to said main section between

a first stowed position, wherein the display screen covers the main section, and a second deployed position wherein said display section is disposed on the top of said main section and, optionally, a portion of the rear section, such that the surface of the display screen is disposed substantially in perpendicular to said main section, and deployed position, wherein the display is raised relative to the main section, substantially in perpendicular thereto, with in-line alignment with the frontal surface of the main section;

The rear section is made to be pivotable relative to the main section between the stowed position, wherein the rear section and the main section are aligned horizontally, and the deployed position wherein the rear section is raised relative to the main section, substantially perpendicular to it.

The display section and the rear section are pivotally connected with the main section such that the display section moves to the deployed state along with the rear section or their pivotal motions occur sequentially.

The main section, display section and rear section have substantially rectangular parallelepiped shape with substantially planar front, rear, top and lateral surfaces.

### BRIEF DESCRIPTION OF THE DRAWINGS

The computer case in accordance with the present invention will be made clear in the following disclosure, with the aid of the attached drawings, wherein:

FIG. 1 shows a computer case known in the art, together with a cathode ray tube display;

FIG. 2 shows a computer case known in the art, together with a liquid crystal display;

FIG. 3 shows a computer case known in the art, with capability of being carried with raised or lowered positions of a display;

FIG. 4 shows a computer case known in the art, that has upper and lower sections;

FIG. 5a shows a schematic view of a computer case according to the present invention in a stowed carriageable position;

FIG. 5b shows a schematic view of a computer case according to the present invention in a deployed working position;

FIG. 6a shows a top view of the case main section according to the present invention, together with the components placed therein;

FIG. 6b shows a lateral view of the case main section according to the present invention, together with the components placed therein;

FIG. 7 shows a front view of the case rear section according to the present invention, together with the components placed therein;

FIGS. 8a to 8f show the deployment stages of the case according to the present invention from the stowed position to the deployed position;

FIG. 9 shows an embodiment of the case according to the present invention is a deployed state, wherein the display section is designed with the capability of changing the inclination angle.

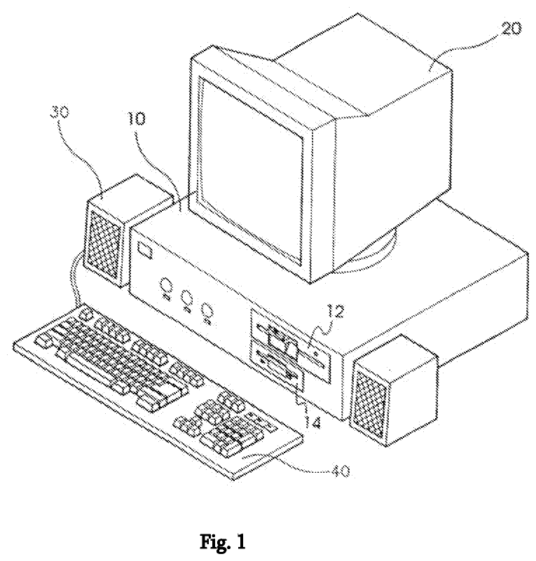

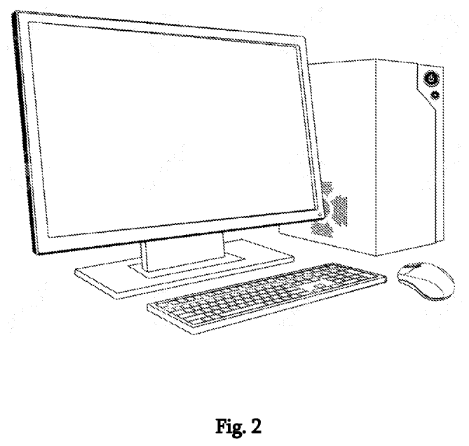

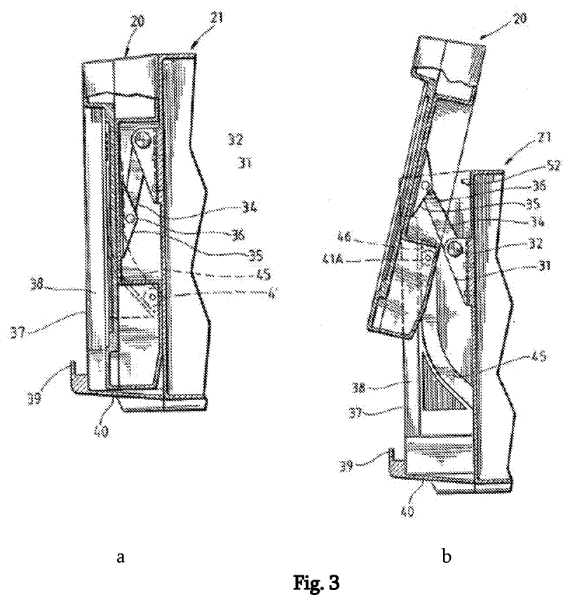

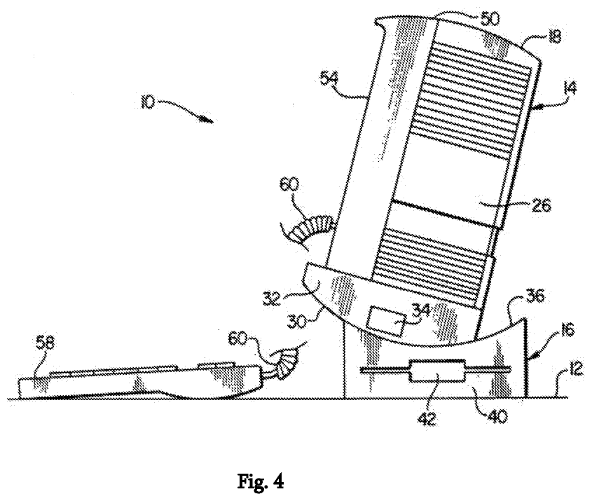

### DETAILED DESCRIPTION

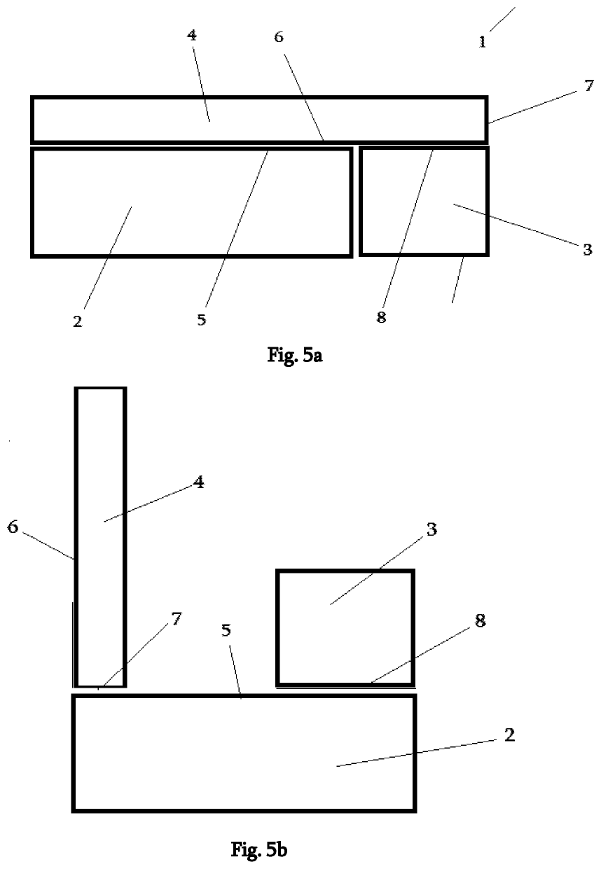

As shown in FIGS. 5a and 5b, the computer case 1 consists of three sections: a main section 2; a rear section 3 capable of being pivoted relative to the main section 2; and a display section 4 capable of being pivoted relative to the main section 2.

Referring to the FIG. 5a, the computer case 1 in a stowed, carriageable, state is shown. In this state the front surface 6 of the display section 4, i.e. the display screen side, is turned towards the top surface 5 of the main section 2. Due to such an arrangement, the display screen (not shown in the figure), which is disposed within the display section 4, is reliably protected from mechanical damage from outside, especially when carrying the case 1.

Referring to FIG. 5b, the computer case 1 in a deployed, working, state is shown. In this state, the display section 4 is disposed in front of the main section 2 in a vertical position, its frontal surface 6 (display screen side) being directed away from the frontal side of the main section 2, and the rear section 3 is disposed in a vertical position at the rear side of the main section 2, the top surface 8 of which faces the top surface of the main section 2, and the lower surface 7 of the display section 4 faces the top surface 5 of the main section 2.

Such a case in its stowed state takes the shape of an ordinary desktop computer, and the computer can be placed on a table when deployed without occupying significant working space.

Owing to such a design, the case according to the present invention forms a dense construction that is highly convenient to carry. It takes the shape of a substantially rectangular parallelepiped and it can be held in a hand like a handheld suitcase when carrying. It should also be noted that all components within the computer metal case are properly protected. For example, the display screen surface, which must be handled with special care, faces the inside of the case, while the rear surface of the display is properly protected by the metal case surface.

When the computer case is in the stowed state, the rear section covers the main section and restricts access to its components, such as the motherboard, and when it is in the deployed state, the components of the main section become accessible. For example, when trying to repair the computer, it is very usable that the display section is placed in front of the main section, thereby enabling access to the main section components.

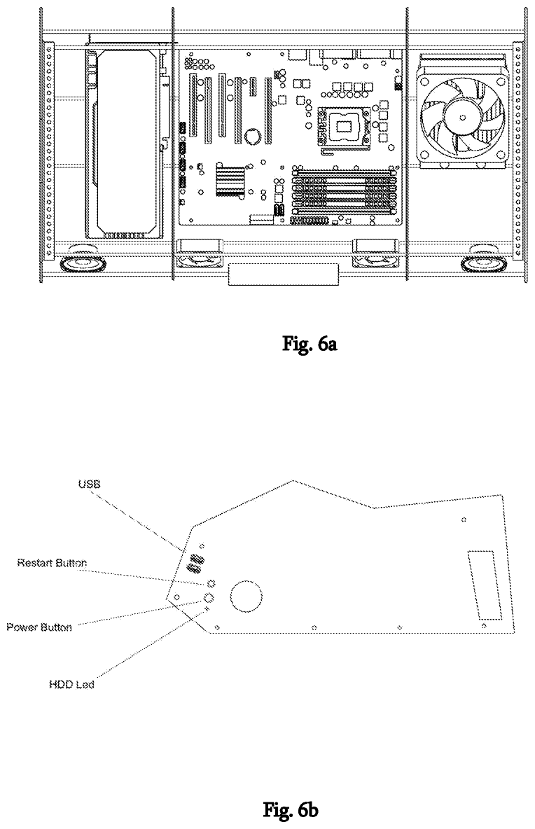

Referring to FIGS. 6a and 6b, an axonometric view of the main section together with the computer component accommodated therein is shown. The main section usually accommodates the components such as a motherboard, a suction fan and an air-ejector fan that suck air from the front side of the main section, speakers, a processor cooler.

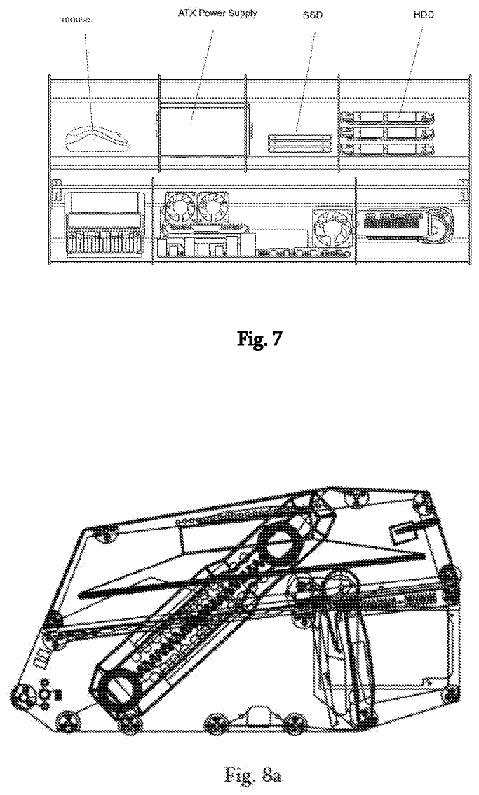

Referring to FIG. 7, the rear section is shown. It can accommodate the computer components, such as a power supply unit, hard disc, a compartment for placing a computer mouse, etc.

Owing to such distribution of the components, they can be extremely effectively cooled when the display section and the rear section are in a vertical position when being in the working state. This is because the air stream sucked from the frontal side of the case almost without any obstruction passes through the main section towards its open end, and the additional air-ejector fans mounted at the end of the main section direct the air stream towards the rear section and, at the same time, the components within the rear section are effectively cooled. The end section of the top surface of the main section is perforated for providing a passageway to the heated air to allow it to leave the main section. Also perforated is one of the surfaces of the rear section. The power supply unit disposed within the rear section is isolated and the air heated by it passes from the computer into the outer space such that the heated air is not in contact with the components disposed within the main section.

The main section in turn is divided into three sections, one of which accommodates a videocard and videocard cooling fan that sucks air from underneath the case and pushes it outwards. It is worth noting that the air is sucked into the main section from outside.

Since there is a capability of an effective cooling it is possible to use powerful components in terms of data processing. Moreover, access to the components becomes easier and therefore the computer is much easier to be repaired and its components can be replaced without any difficulty.

Moreover, by disposing the motherboard and other component in different sections, the computer can be better used and can more effectively be placed in a working space.

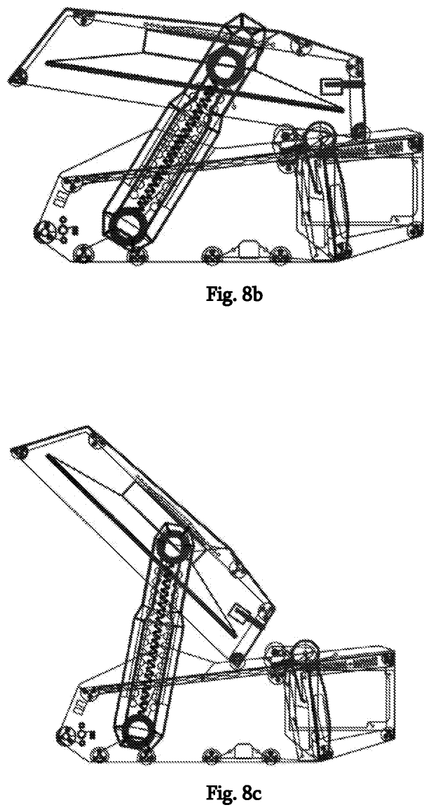

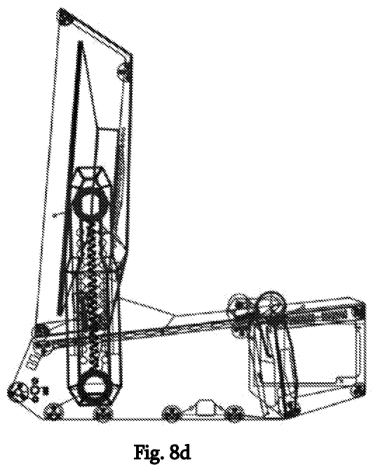

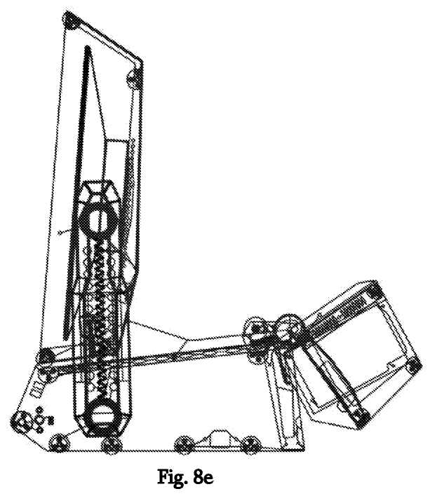

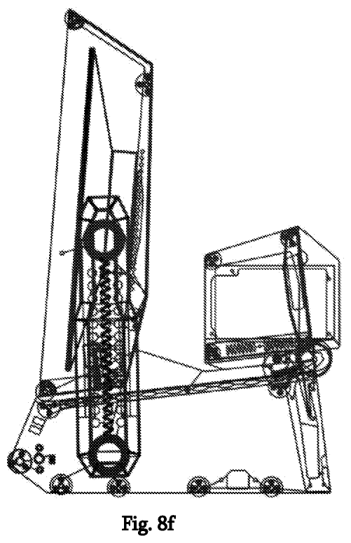

Referring to FIGS. 8a to 8g, various stages of the computer case deployment, from the stowed position into the deployed position, are shown.

The computer case system comprises mechanisms for pivoting the display section and the rear section (not shown in figures) to enable them to perform motions between the deployed and stowed positions. In a preferable embodiment of the present invention, the pivoting mechanisms are operably connected to each other such that the rear section mechanically performs the pivotal motion when the display section performs the pivotal motion, or the rear section starts performing pivotal motion once the display section takes the deployed or stowed position. Such mechanisms can be embodied in a variety of modifications, e.g. as a drive mechanism connected to an electric motor, and the like, that are well known to those skilled in the art.

The display section is connected with the main section by means of a pair of pivotable elements (arms), one end of which is attached to the lateral walls of the main section, e.g. by a pin, with the capability of being pivoted, and another end is attached to the lateral walls of the display section, e.g. by a pin, with the capability of being pivoted.

As concerns the rear section, its front side is attached to the main section by means of shafts being common to the both of the sections, the shafts extending horizontally through the ends of the main and rear sections such that the rear section is capable of pivoting relative to the main section without the need of a single common through shaft.

Once it has been brought to a place, the computer is placed, for example on an office table, in a horizontal state. A retaining mechanism comprises a fixing hook and button for releasing the fixation (not shown in the figure). By pushing the button, the computer case deployment mechanism is put into operation and the display section and the rear section start deploying simultaneously or sequentially. In the final deployed position, the display section and the rear section are disposed substantially in parallel to each other and in perpendicular to the main section. In this position, the entire case in fact takes a shape of a hexahedron which is beneficial inasmuch as the computer system is placed without having to occupy significant working space. In addition, a channel is made through the retaining mechanism wherein cables for connecting the main and rear sections pass.

Due to the fact that the retaining mechanism limits the maximum angle between the computer case sections, the sections stably retain the angle (e.g. 90 degree angle) between them. It should be noted that the retaining mechanism is destined for fixing the display section and the rear section alike.

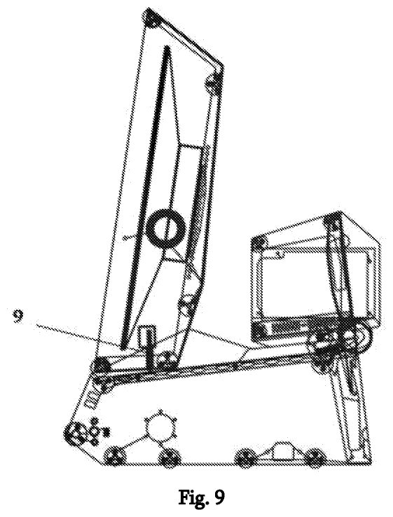

According to one embodiment of the present invention, in order to make the computer case more ergonomic-friendly, variation of the display section inclination angle is contemplated. In the embodiment shown in FIG. 9, the variation of the inclination angle of the display section is effected by means of motion of a metal pin 9 fastened to the display section (e.g. by means of an electric motor) which enables forward and backward motion of the same section relative to a support axis.

Unlike the computer case according to the present invention, In conventional computer cases, different external cables have to be used for coupling the printed circuit board with the display.

In order to avoid the damage of cabling in result of bending and straightening them due to the repeated motion of the display section relative to the main section, an axial hollow passageway is made within the juncture of the display section and the hollow section to allow the cables to pass therethrough. Conventional multi-core cables are basically used for this purpose.

The computer having the structure according to the present invention can easily be modified, i.e. reconfigured by replacing, removing and/or adding some components. Such procedures are usually time consuming in conventional computers because several components have to be dismantled when there is a need to replace e.g. a motherboard covered by some of the components. In contrast, the structure according to the present invention enables rapid and easy access to the internal components. Moreover, components of various sizes can be chosen and replaced, e.g. flat screen displays of various grades can be disposed in the display section.

1. A computer case, comprising:
a main section for accommodating at least a first group of computer components;
a display section for accommodating a display device therein; and
a rear section for accommodating at least a second group of computer components,
wherein a display section is pivotally connected to said main section with the capability of being pivoted with respect to said main section between a first stowed position, wherein the display section is disposed at the top of said main section such that the surface of the display screen faces the top surface of said main section substantially in parallel thereto, and a second deployed position, wherein said display section is disposed on a top of said main section such that the surface of the display screen is disposed substantially perpendicular to said main section and in in-line alignment with the frontal surface of the main section, and
wherein said rear section is pivotally connected to said main section with the capability of being pivoted with respect to said main section substantially about a horizontal axis of rotation, between a first position wherein said rear section and said main section are disposed side by side in the same plane, and a second position wherein said rear section is substantially perpendicular to said main section, and wherein said main section and said rear section are disposed substantially parallel to each other.

2. A computer case in accordance with claim 1, wherein said main section, display section and rear section have a substantially rectangular parallelepiped shape with substantially planar front, rear, top and lateral surfaces.

3. A computer case in accordance with claim 1, wherein said first group of computer components comprises a motherboard, air suction fans and air-ejector fans for sucking the air from the front side of said main section, speakers, a processor cooler, and a videocard; and said second group of computer components comprises a power supply unit, a hard disc, and a compartment for accommodating a computer mouse.

4. A computer case in accordance with claim 2, wherein said display section is pivotally connected to said main section by means of an arm having one end pivotally attached to the lateral surface of said main section, and having another end pivotally attached to the lateral surface of said display section.

5. A computer case in accordance with claim 1, wherein said main section, display section and rear section are made of a metal.

6. A computer case in accordance with claim 1, that comprises a retaining mechanism for locking said display section and said rear section in the first position.

7. A computer case in accordance with claim 6, wherein said retaining mechanism comprises a retaining hook and a retention releasing button.
